(19) United States
(12) Patent Application Publication
(10) Pub. No.: US 2022/0285408 A1
(43) Pub. Date: Sep. 8, 2022

(54) ISOLATION STRUCTURE OF A PHOTORESIST STRIPPER, TFT ARRAYS AND PREPARATION METHOD THEREOF

(71) Applicant: Chongqing Konka Photoelectric Technology Research Institute Co., Ltd., Chongqing (CN)

(72) Inventors: Liu Chung Lee, Chongqing (CN); Tzu Ping Lin, Chongqing (CN)

(21) Appl. No.: 17/280,098

(22) PCT Filed: Nov. 26, 2019
(86) PCT No.: PCT/CN2019/120763

§ 371 Date: Mar. 25, 2021

(51) Int. Cl. H01L 27/12; H01L 21/02

(52) U.S. Cl. CPC H01L 27/1259; H01L 27/1248; H01L 21/02252; H01L 21/31127

(57) ABSTRACT

Disclosed are an isolation structure of a photoresist stripper, a TFT array, and preparation methods thereof. The isolation structure includes a protective layer and a hardened layer arranged on the protective layer. The hardened layer is formed by plasma bombarding the protective layer with gas(es) and is configured to insulate the photoresist stripper. By forming the hardened layer on the surface of the protective layer including the organic planar layer, the hardened layer can prevent chemical agents (such as photoresist stripper) adopted in the subsequent process from getting into the protective layer, so as to keep the photoresist stripper from the protective layer, protecting the protective layer.

### TECHNICAL FIELD

The present disclosure relates to thin film transistor (TFT) arrays, in particular to isolation structures of photoresist strippers, TFT arrays and preparation methods thereof.

### BACKGROUND OF THE INVENTION

When preparing TFT array matrices in the prior art, as shown in FIG. 1, an electrode 2, an organic planar layer 3 and a transparent conductive film made of indium tin oxide conductor (ITO for short) layer is sequentially first prepared on a glass substrate 1, and a lithography process is then performed. Organic residues on photoresist 5 (specifically photosensitive photoresist) and electrode opening region (i.e. the region opened after exposure and development) are removed by a photoresist stripper that is needed. However, since the organic planar layer is not completely covered by the ITO layer 4, the photoresist stripper is passed into the segments of the organic planar layer that are not covered by ITO layer 4, making the organic planar layer swell. Bulge(s) 21 at the swelled portion(s) may lift the ITO layer 4 (as shown in FIG. 2), causing the ITO layer 4 to be peeled off. Once a gap appears between the ITO layer 4 and the organic planar layer 3, the photoresist stripper can more easily get into the organic planar layer.

Therefore, the existing technology needs to be further improved and developed.

### SUMMARY OF THE INVENTION

An isolation structure of a photoresist stripper, a TFT array and preparation methods thereof are provided in the present disclosure in other to solve the problem(s) mentioned above, that is to solve the problem of the swell of the organic planar layer caused by the penetration of the photoresist stripper.

Technical solutions adopted by the present disclosure to solve the aforesaid technical problem(s) are as follows.

An isolation structure of a photoresist stripper may comprise: a protective layer, and a hardened layer arranged on the protective layer. The hardened layer may be formed by plasma bombarding the protective layer with a gas and be configured for insulating the photoresist stripper.

In an embodiment of the isolation structure of the photoresist stripper, the gas may include one or more of Ar, N₂, and BCl₃.

In an embodiment of the isolation structure of the photoresist stripper, the protective layer may include an organic planar layer.

In an embodiment of the isolation structure of the photoresist stripper, the isolation structure may further comprise: an electrode arranged under the organic planar layer.

In an embodiment of the isolation structure of the photoresist stripper, the isolation structure may further comprise: an ITO layer arranged on the hardening layer and a photoresist layer arranged on the ITO layer.

In any one aforesaid embodiment of the isolation structure of the photoresist stripper, the parameters of the plasma bombardment may include: temperature: 20-30° C.; pressure: 10-30 mT; bombardment time: 10-20 s; and power density: 2000˜3000 w/cm².

In any one aforesaid embodiment of the isolation structure of the photoresist stripper, the photoresist stripper may comprise dimethyl sulfoxide and ethanolamine.

A method for preparing an isolation structure of a photoresist stripper, wherein the method for preparing the isolation structure may include the following steps:
providing a protective layer; and
plasma bombarding the protective layer with a gas, and forming a hardened layer on the protective layer to obtain the isolation structure of the photoresist stripper, the hardened layer being configured to insulate the photoresist stripper.

In an embodiment of the method for preparing the isolation structure of the photoresist stripper, the gas may include one or more of Ar, N₂, and BCl₃.

In an embodiment of the method for preparing the isolation structure of the photoresist stripper, the protective layer may be an organic planar layer.

In an embodiment of the method for preparing the isolation structure of the photoresist stripper, the parameters of the plasma bombardment may be: temperature: 20-30° C.; pressure: 10-30 mT; bombardment time: 10-20 s; and power density: 2000-3000 w/cm².

In an embodiment of the method for preparing the isolation structure of the photoresist stripper, the photoresist stripper may be dimethyl sulfoxide and ethanolamine.

A method for preparing a TFT array may include the following steps:
providing a substrate;
preparing an electrode on the substrate;
preparing a protective layer on the electrode, the protective layer being an organic planar layer; and
preparing a hardened layer on the organic planar layer by adopting the method for preparing the isolation structure of the photoresist stripper according to any one aforesaid embodiment.

In an embodiment of the method for preparing the TFT array, the method for preparing the TFT array may further include the following steps:
preparing an ITO layer on the hardened layer;
preparing a photoresist layer on the ITO layer and performing photolithography processing; and
performing stripping processing on the photoresist layer by using the photoresist stripper.

The beneficial effect of the present disclosure may be as follows: by forming the hardened layer on the surface of the protective layer including the organic planar layer, the hardened layer can prevent chemical agents (such as photoresist stripper) adopted in the subsequent process from getting into the protective layer, so as to keep the photoresist stripper from the protective layer, protecting the protective layer.

### BRIEF DESCRIPTION OF THE DRAWINGS

FIG. 1 is a schematic diagram of a conventional preparation for TFT array;

FIG. 2 is a schematic diagram showing the ITO layer peeled off in the conventional preparation;

FIG. 3 is a schematic diagram of the structure of the protective layer according to the present disclosure;

FIG. 4 is a schematic diagram of the structure of the protective layer and the hardened layer according to the present disclosure;

FIG. 5 is a schematic diagram of the structure of the protective layer, the hardened layer and the ITO layer according to the present disclosure;

FIG. 6 is a schematic diagram of the structure of the protective layer, the hardened layer, the ITO layer and the photoresist layer according to the present disclosure;

FIG. 7 is a schematic diagram of photomask processing according to the present disclosure;

FIG. 8 is a schematic diagram of the photoresist layer after development according to the present disclosure;

FIG. 9 is a schematic diagram of the photoresist layer and the ITO layer after etching processing according to the present disclosure;

FIG. 10 is a schematic diagram of the ITO layer and the hardened layer after stripping processing according to the present disclosure;

FIG. 11 is a flow chart of the method for preparing the isolation structure of the photoresist stripper according to the present disclosure; and

FIG. 12 is a flow chart of the method for preparing the TFT array according to the present disclosure.

### DETAILED DESCRIPTION

The present disclosure can be further described in detail below with reference to the accompanying drawings and embodiments so as to make the objectives, technical solutions and advantage of the present disclosure more clearer and explicit. It shall be appreciated that the specific embodiments described herein are only used to explain and not to limit the present disclosure.

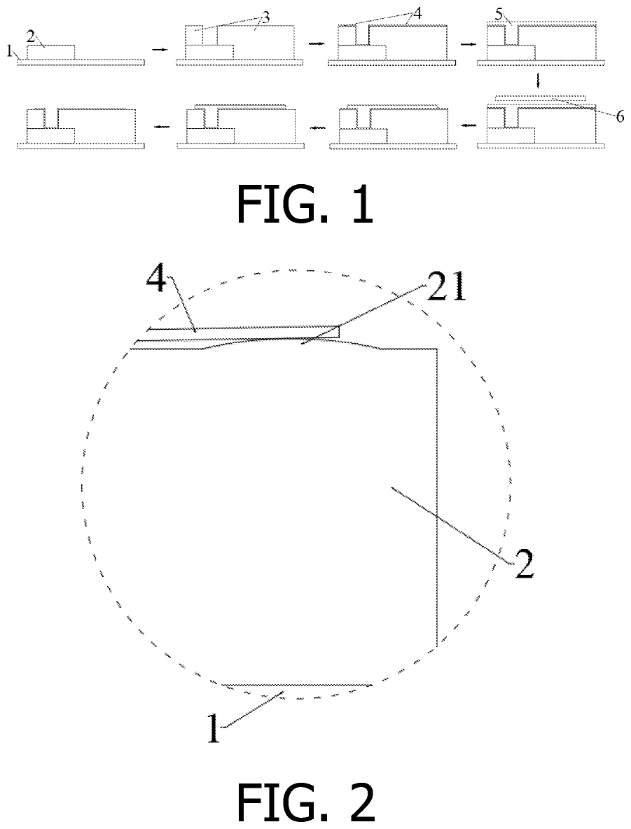

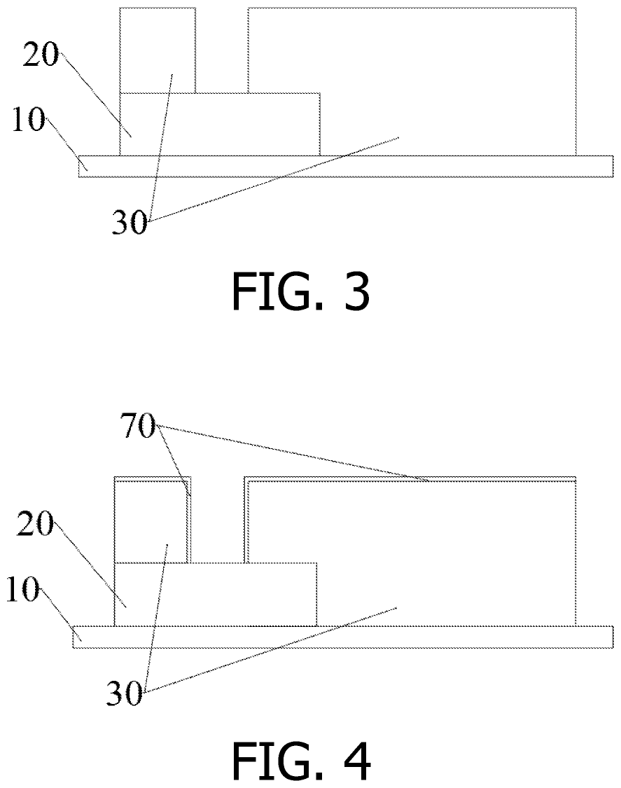

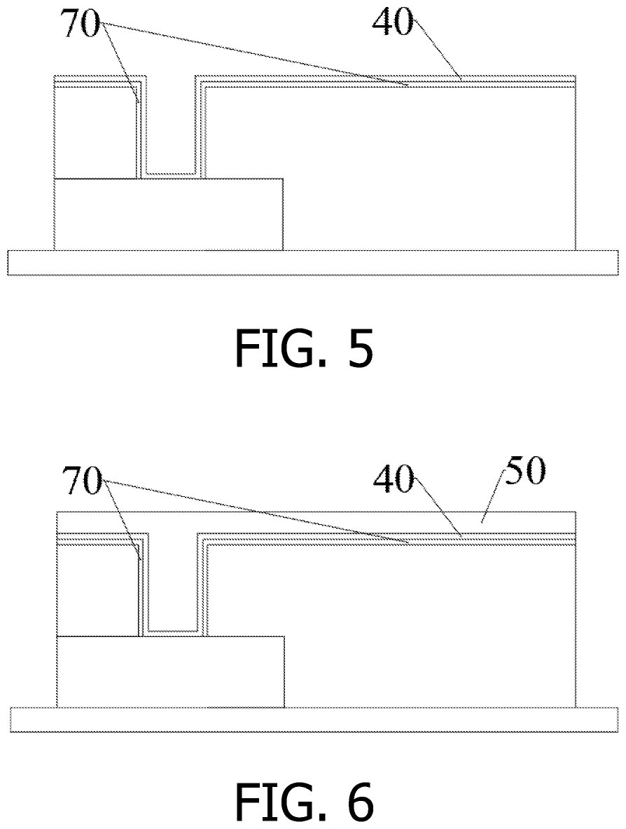

Please refer to some embodiments of the present disclosure shown in FIGS. 1 to 10, provided is an isolation structure of a photoresist stripper.

As shown in FIG. 1, during a conventional preparation for a TFT array, an ITO layer 4 having a preset pattern may be obtained by performing a lithography process on a transparent conductive film made of indium tin oxide conductor (ITO for short) layer. In the lithography process, a photoresist is usually coated onto the ITO layer 4 to form a photoresist layer 5 which is then exposed under a photomask 6 having a structure being reversed to the preset pattern. The exposed photoresist layer 5 accordingly also has a present pattern. The segment(s) of the photoresist layer that may not be exposed is removed by developing, the corresponding segment(s) of the ITO layer is then removed by etching, retaining the segment(s) of the ITO layer corresponding to the unexposed segment(s) of the photoresist layer. A photoresist stripper is used to remove the photoresist layer to obtain the ITO layer having the preset pattern.

However, the ITO layer 4 is usually arranged on the organic planar (protective) layer. The protective layer 3 is exposed after removing the ITO layer corresponding to the photoresist layer. When using the photoresist stripper in the subsequent process to remove the exposed photoresist layer 5, the photoresist stripper may penetrate into the protective layer 3, causing the protective layer 3 to be swelled; accordingly, the swelled portion may lift the ITO layer, leading to the ITO layer to be peeled off. Once there is a gap between the ITO layer and the protective layer 3, the photoresist stripper can more easily get into the protective layer 3 from the gap. It is naturally not limited to the protective layer 3; other functional layer(s) (such as the bank layer on the electrode) also have similar problem in other application scenarios. The functional layers mentioned above are collectively referred to as protective layer in the present disclosure.

To solve the above-mentioned problem of the swell of the protective layer caused by the penetration of the photoresist stripper, an isolation structure of a photoresist stripper provided in the present disclosure, as shown in FIG. 4, may include a protective layer 30 and a hardened layer 70 arranged on the the protective layer 30. The hardened layer 70 is formed by plasma bombarding the protective layer 30 with gas and is configured to isolate the photoresist stripper. The organic planar layer is described below as the protective layer 30.

The hardened layer 70 is formed on the surface of the protective layer 30 after plasma bombardment. The hardened layer 70 can prevent chemical reagent(s) (such as the photoresist stripper) used in the subsequent process from getting into the protective layer 30 so as to keep the photoresist stripper out of the protective layer 30, protecting the protective layer 30.

In addition, the hardened layer 70 can also block moisture and prevent moisture from entering the protective layer 30. Plasma bombardment can keep the hardened layer 70 good in roughness and penetration, which is beneficial to the homogenization and penetration of light.

The gas includes one or more of Ar, N₂ and BCl₃ in a preferred embodiment of the present disclosure. Specifically, gases with relatively stable physical and chemical properties and uneasy involvement in reaction (such as N₂, He and Ar) that are employed can also protect the protective layer 30 from the influence of impurity ions. Gases such as BCl₃ can also be used for rapid formation of the hardened layer 70, increasing the density of the hardened layer 70 and enhancing the isolation ability of the hardened layer 70.

During the process of plasma bombardment, the above-mentioned gases form plasma which can be manufactured in situ or remotely manufactured and then flowed into a plasma bombardment chamber. Various application methods for producing plasma, including capacitively coupled plasma, inductively coupled plasma, magnetron plasma, electron cyclotron resonance, or microwave, can be employed. The plasma may have a high ion density.

The parameters of plasma bombardment in a preferred embodiment of the present disclosure are: temperature: 20-30° C.; pressure: 10-30 mT; bombardment time: 10-20 s; and power density: 2000˜3000 w/cm². Specifically, under such parameters of plasma bombardment, a hardened layer 70 with a thickness of 10 nm˜100 nm can be obtained. The thickness of the hardened layer 70 shall not be too thick or too thin; when it is too thick, the penetration efficiency of the protective layer may be decreased; and when it is too thin, the photoresist stripper cannot be completely insulated.

The isolation structure may further include an electrode 20 arranged under the protective layer in a preferred embodiment of the present disclosure, as shown in FIGS. 4 to 6. The isolation structure may further include an ITO layer 40 arranged on the hardened layer 70 and a photoresist layer 50 arranged on the ITO layer 40.

The photoresist stripper may be an organic alkali, for example the photoresist stripper may include dimethyl sulfoxide (DMSO) and ethanolamine (MEA), in a preferred embodiment of the present disclosure. Specifically, the photoresist stripper TOK-106 (30 wt % DMSO and 70 wt % MEA) is adopted. Other photoresist stripper such as NAGASE & CO., LTD (N-300) can naturally also be employed.

In accordance with the isolation structure of the photoresist stripper described in any one of the above embodiments, a TFT array is also provided in a preferred embodiment of the present disclosure.

The TFT array according to an embodiment of the present disclosure may include the isolation structure of the photoresist stripper described in any one of the above embodiments which is described in detail above.

In accordance with the isolation structure of the photoresist stripper described in any one of the above embodiments, a method for preparing the isolation structure of the photoresist stripper is also provided in a preferred embodiment of the present disclosure.

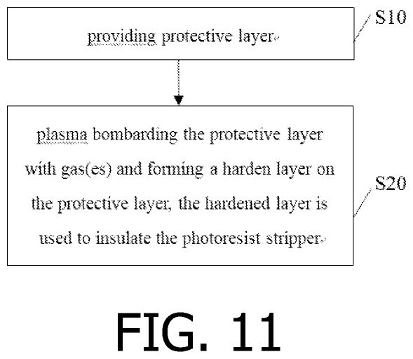

A method for preparing the isolation structure of the photoresist stripper provided in an embodiment of the present disclosure may include the following steps, as shown in FIG. 11:

Step S10: providing a protective layer 30.

The protective layer 30 may be specifically an organic planar layer or a bank layer.

Step S20: plasma bombarding the protective layer 30 with gas, and forming a hardened layer 70 on the protective layer to obtain the isolation structure of the photoresist stripper; wherein the hardened layer 70 is configured to insulate the photoresist stripper.

In a preferred embodiment of the present invention, the gas includes one or more of Ar, N₂, and BCl₃. Specifically, the use of gases with relatively stable physical and chemical properties such as N₂, He, and Ar, which are not easy to participate in the reaction, can also protect the protective layer 30 from the influence of impurity ions; and gases such as BCl₃ can also be used for rapid formation. The hardened layer 70 increases the density of the hardened layer 70 and improves the isolation ability of the hardened layer 70.

The parameters of plasma bombardment in a preferred embodiment of the present disclosure are: temperature: 20-30° C.; pressure: 10-30 mT; bombardment time: 10-20 s; and power density: 2000˜3000 w/cm². Specifically, under such parameters of plasma bombardment, a hardened layer 70 with a thickness of 10 nm˜100 nm can be obtained. The thickness of the hardened layer 70 shall not be too thick or too thin; when it is too thick, the penetration efficiency of the protective layer may be decreased; and when it is too thin, the photoresist stripper cannot be completely insulated.

The photoresist stripper may include dimethyl sulfoxide (DMSO) and ethanolamine (MEA) in a preferred embodiment of the present disclosure; for example, adopting the photoresist stripper TOK-106 (30 wt % DMSO and 70 wt % MEA). Other photoresist stripper may specifically also be employed. Since organic materials are used in the protective layer, they and the photoresist stripper are easily penetrated into the protective layer, causing the protective layer to be swelled and the ITO layer 40 to be peeled off.

In accordance with the method for preparing the isolation structure of the photoresist stripper described in any one of the above embodiments, a method for preparing a TFT array is also provided in a preferred embodiment of the present disclosure.

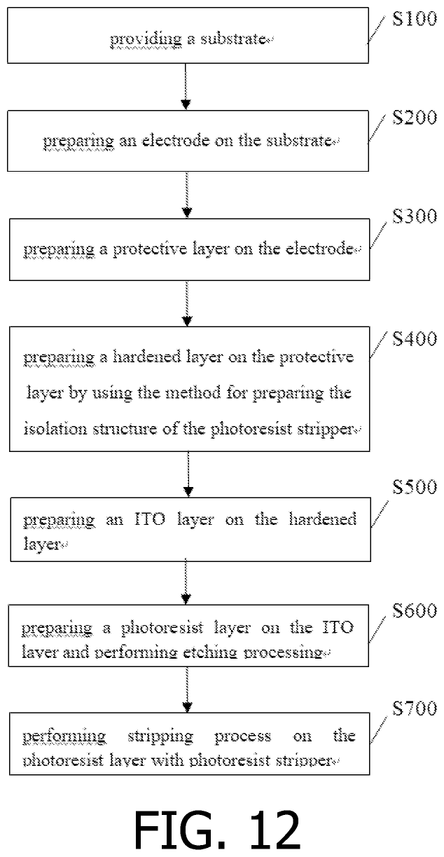

A method for preparing a TFT array provided in an embodiment of the present disclosure may include the following steps, as shown in FIG. 12:

Step S100: providing a substrate 30.

Step S200, preparing an electrode 20 on the substrate 10.

The substrate 10 in the present disclosure may specifically be a glass substrate, a silicon substrate, a flexible substrate, or the like. The electrode 20 here naturally can be a cathode or an anode.

Step S300: preparing a protective layer 30 on the electrode 20; wherein the protective layer 30 is an organic planar layer or a bank layer, which is specifically described above.

Step S400: preparing a hardened layer 70 on the protective layer by using any one of the above-mentioned methods for preparing the isolation structure of the photoresist stripper.

The hardened layer 70 is specifically formed by plasma bombarding the protective layer 30.

Step S500: preparing an ITO layer 40 on the hardened layer 70.

The ITO layer 40 may specifically be prepared by a deposition process.

Step S600: preparing a photoresist layer 50 on the ITO layer 40 and performing photolithography processing.

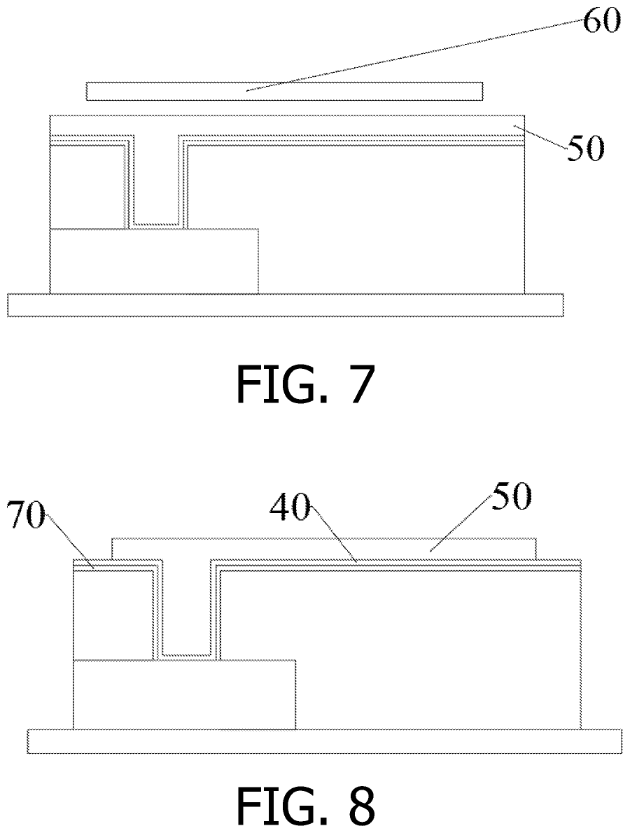

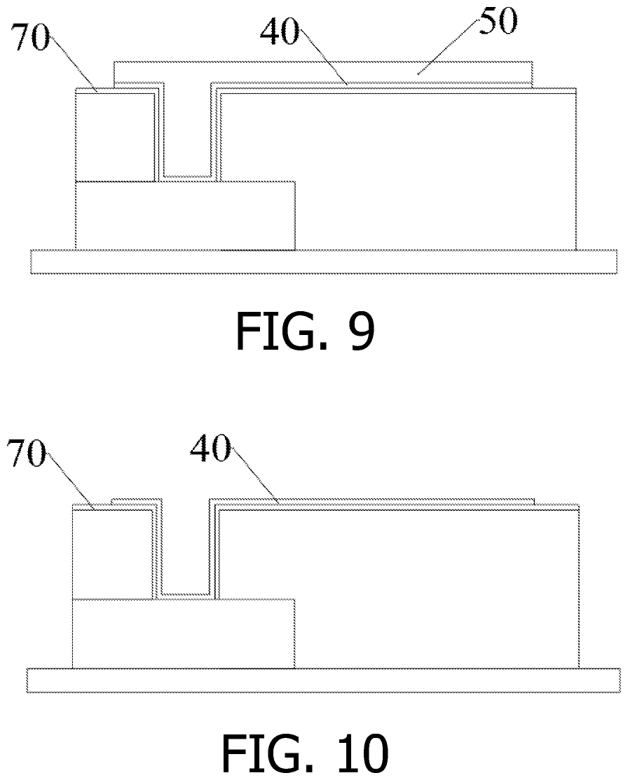

The photolithography here may specifically include: photomask, exposure, development, etching, etc.; and of course, photolithography processing may also include drying, detecting, cleaning and other steps. As shown in FIG. 7, the process of photomask is to use a photomask 60 to align and block the photoresist layer 50, then perform exposure processing, later remove unexposed photoresist layer with a development process (as shown in FIG. 8), and finally etch the ITO layer corresponding to the unexposed photoresist layer with an etch process (as shown in FIG. 9).

Step S700: performing stripping processing on the photoresist layer 50 by using a photoresist stripper.

As shown in FIGS. 6-10, specifically, after photolithography is completed, the remaining photoresist layer 50 is needed to be performed stripping processing with a photoresist stripper. Since the hardened layer 70 is formed on the protective layer in the present disclosure, after the ITO layer 40 corresponding to the unexposed photoresist layer 50 is removed, the hardened layer 70 is exposed and the protective layer is not exposed. On the one hand, the hardened layer 70 is relatively dense, and the photoresist stripper cannot penetrate the hardened layer 70 and penetrate into the protective layer. On the other hand, the hardness of the hardened layer 70 is relatively high; even if the photoresist stripper is penetrated into the protective layer, the hardened layer 70 with high hardness may hamper the protective layer from being swelled, and the (nano-level) rough hardened layer 70 may strengthen the adhesion between the protective layer and the ITO layer 40, further preventing the ITO layer 40 from being fallen off the hardened layer 70.

In conclusion, an isolation structure of a photoresist stripper, a TFT array, and preparation methods thereof are provided in the present disclosure, in which the isolation structure includes a protective layer and a hardened layer arranged on the protective layer. The hardened layer is formed by plasma bombarding the protective layer with gas(es) and is configured to insulate the photoresist stripper. By forming the hardened layer on the surface of the protective layer including the organic planar layer, the hardened layer can prevent chemical agents (such as photoresist stripper) adopted in the subsequent process from getting into the protective layer, so as to keep the photoresist stripper from the protective layer, protecting the protective layer.

It shall be understood that the application of the present disclosure is not limited to the above examples. For those of ordinary skill in the art, improvements or changes can be made based on the above description, and all these improvements and changes should fall within the protection scope of the appended claims of the present disclosure.

1. An isolation structure of a photoresist stripper, comprising: a protective layer, and a hardened layer arranged on the protective layer; the hardened layer being formed by plasma bombarding the protective layer with a gas and being configured for insulating the photoresist stripper.

2. The isolation structure of the photoresist stripper according to claim 1, wherein the gas comprises one or more of Ar, N₂, and BCl₃.

3. The isolation structure of the photoresist stripper according to claim 1, wherein the protective layer includes an organic planar layer.

4. The isolation structure of the photoresist stripper according to claim 3, wherein the isolation structure further comprises: an electrode arranged under the organic planar layer.

5. The isolation structure of the photoresist stripper according to claim 4, wherein the isolation structure further comprises: an ITO layer arranged on the hardening layer and a photoresist layer arranged on the ITO layer.

6. The isolation structure of the photoresist stripper according to claim 1, wherein the parameters of the plasma bombardment include: a temperature of 20-30° C.; a pressure of 10-30 mT; a bombardment time of 10-20 s; and a power density of 2000-3000 w/cm².

7. The isolation structure of the photoresist stripper according to claim 1, wherein the photoresist stripper comprises dimethyl sulfoxide and ethanolamine.

8. A method for preparing an isolation structure of a photoresist stripper, wherein the method for preparing the isolation structure comprises the following steps:
providing a protective layer; and
plasma bombarding the protective layer with a gas and forming a hardened layer on the protective layer to obtain the isolation structure of the photoresist stripper, the hardened layer being configured to insulate the photoresist stripper.

9. The method for preparing the isolation structure of the photoresist stripper according to claim 8, wherein the gas comprises one or more of Ar, N₂, and BCl₃.

10. The method for preparing the isolation structure of the photoresist stripper according to claim 8, wherein the protective layer includes an organic planar layer.

11. The method for preparing the isolation structure of the photoresist stripper according to claim 8, wherein the parameters of the plasma bombardment include: a temperature of 20-30° C.; a pressure of 10-30 mT; a bombardment time of 10-20 s; and a power density of 2000-3000 w/cm².

12. The method for preparing the isolation structure of the photoresist stripper according to claim 8, wherein the photoresist stripper includes dimethyl sulfoxide and ethanolamine.

13. A method for preparing a TFT array, wherein the method for preparing a TFT array comprises the following steps:
providing a substrate;
preparing an electrode on the substrate;
preparing a protective layer on the electrode, the protective layer being an organic planar layer; and
preparing a hardened layer on the organic planar layer by adopting the method for preparing the isolation structure of the photoresist stripper according to claim 8.

14. The method for preparing the TFT array according to claim 13, wherein the method for preparing the TFT array further comprises the following steps:
preparing an ITO layer on the hardened layer;
preparing a photoresist layer on the ITO layer and performing photolithography processing; and
performing stripping processing on the photoresist layer by using the photoresist stripper.
